(19) United States
(12) Patent Application Publication
(10) Pub. No.: US 2015/0068719 A1
(43) Pub. Date: Mar. 12, 2015

(54) HEAT SINK

(71) Applicant: DELTA ELECTRONICS, INC., Taoyuan Hsien (TW)

(72) Inventors: Chao-Wen LU, Taoyuan Hsien (TW); Chun-Chih WANG, Taoyuan Hsien (TW)

(73) Assignee: DELTA ELECTRONICS, INC., Taoyuan Hsien (TW)

(21) Appl. No.: 14/279,872

(22) Filed: May 16, 2014

(30) Foreign Application Priority Data
Sep. 6, 2013 (TW) 102132171

(51) Int. Cl. F28F 3/00; H05K 7/20

(52) U.S. Cl. CPC F28F 3/00; H05K 7/2039
USPC 165/185

(57) ABSTRACT

A heat sink includes a heat conduction portion and a heat dissipation portion. The heat conduction portion has a thickness, and a flat portion of the heat conduction portion contacts a heat source. The heat dissipation portion is extended from at least one side of the thickness of the heat conduction portion and includes at least a bending portion including a plurality of holes.

### CROSS REFERENCE TO RELATED APPLICATIONS

This Non-provisional application claims priority under 35 U.S.C. §119(a) on Patent Application No(s). 102132171 filed in Taiwan, Republic of China on Sep. 6, 2013, the entire contents of which are hereby incorporated by reference.

### BACKGROUND OF THE INVENTION

1. Field of Invention

The invention relates to a heat sink and, in particular, to a heat sink that can be applied to a narrow space.

2. Related Art

With the progress of technologies, the device integration of an electronic product is getting higher and the size thereof is getting smaller. Accordingly, the heat per unit area generated by the electronic product during the operation is raised increasingly. If the heat can not be dissipated properly, the electronic product can be reduced in efficiency and even burned down by heat. Therefore, a heat dissipation apparatus (heat sink) has become indispensible for the electronic product currently.

There are many types for the commonly-used heat dissipation apparatus, such as a heat pipe, vapor chamber or metal sheet without heat pipe. A heat pipe is disposed between a heat source (e.g. a chip) and a heat dissipation fin, operating with a medium therein that can transfer heat by the phase change mechanism. However, when the electronic apparatus using the heat pipe is changed in orientation, the medium in the heat pipe may reflow unexpectedly and the heat conduction effect is thus unstable. Besides, because the heat pipe is an incomplete heat dissipation apparatus, it needs to cooperate with another heat dissipation module (e.g. a metal device or heat dissipation fin), so the related manufacturing will be more complicated and the cost will be raised. In addition, if the heat pipe has a bending portion of a large angle, the flow of the medium therein will be influenced thereby and the heat conduction effect is thus decreased. Besides, if the heat pipe is applied to a narrow space, it needs to be flattened for the proper use but also with weaker structure strength. Accordingly, when the space over the heat source is not enough to contain the heat pipe with the related strengthening structure and fixture, the heat dissipation method by using the heat pipe is not suitable anymore. Therefore, with the trend towards the compactness of the electronic apparatus, the development of the heat pipe applied to the electronic currently encounters a bottleneck.

The vapor chamber operates in the same principle as the heat pipe, but just with a different direction of the heat conduction. The direction of the heat conduction of the heat pipe belongs to one-dimensional conduction, and that of the vapor chamber belongs to two-dimensional conduction so it can dissipate the heat evenly with a lower spreading resistance. However, because the vapor chamber can be considered a kind of two-dimensional development of the heat pipe, the shortcomings of the heat pipe are also included in the vapor chamber and the manufacturing cost may be higher than the heat pipe.

For the electronic apparatus that doesn't use the heat pipe for the heat conduction and dissipation, the metal material of high heat conductivity, such as copper or aluminum, is used on the surface of the heat source and extended to the adjacent fan to become a part, such as an upper cover, of the fan for the heat dissipation. However, before transferred to the fan, the heat needs to travel through the heat conduction material, usually in a thin-plate form with a bad heat conduction effect, that has a certain length and is disposed between the heat source (e.g. a chip) and the fan, the heat conduction effect will get some loss during the traveling path. Accordingly, this kind of heat conduction method provides a limited and unsatisfying efficiency. Therefore, it is an important subject to provide a better heat dissipation mechanism that can be applied to a narrow space.

### SUMMARY OF THE INVENTION

In view of the foregoing subject, an objective of the invention is to provide a heat dissipation apparatus, i.e. heat sink, that can be applied to a narrow space.

A heat sink according to the invention includes a heat conduction portion and a heat dissipation portion. The heat conduction portion has a thickness, and a flat portion of the heat conduction portion contacts a heat source. The heat dissipation portion is extended from at least one side of the thickness of the heat conduction portion and includes at least a bending portion including a plurality of holes.

In one embodiment, the bending portion has a wavy shape, a jagged shape, a ladder-like shape or an alternate arrangement, or their combinations.

A heat sink includes a heat conduction portion and a heat dissipation portion. The heat conduction portion has a thickness, and a flat portion of the heat conduction portion contacts a heat source. The heat dissipation portion is extended from at least one side of the thickness of the heat conduction portion, and includes at least a first branch and a plurality of second branches which are extended outward from at least one side of the thickness of the first branch.

In one embodiment, a difference in level exists between the heat conduction portion and the heat dissipation portion.

In one embodiment, when the heat dissipation portion includes a plurality of first branches, at least two of the first branches are disposed on different levels.

In one embodiment, at least two of the second branches are disposed on different levels.

In one embodiment, the second branches have the same or different interval therebetween.

In one embodiment, the two second branches oppositely extended from the adjacent first branches are connected to each other.

In one embodiment, the heat conduction portion and the heat dissipation portion are integrated into a single structure.

In one embodiment, the heat conduction portion and the heat dissipation portion have the same or different thickness and/or level along the direction perpendicular to the heat source.

In one embodiment, the flat portion of the heat conduction portion is extended to provide a heat dissipation structure that is opposite to the heat source and has a pillar or fin or their combination.

In one embodiment, at least a flow guiding structure is disposed in the space formed by a side of the heat source and the flat portion of the heat conduction portion contacting the heat source.

In one embodiment, the height of the heat sink is between 0.5 mm and 6.5 mm.

As mentioned above, according to the heat sink of the invention applied to a narrow space, a heat conduction material of a certain thickness disposed on the top of the heat source is expanded horizontally to generate a branch structure and vertically changed in shape. Therefore, the heat sink is designed on the basis of the concept of horizontal and vertical structures so as to create three-dimensional airflow channels, so that the windward area and the heat exchange area between the heat sink and the air can be both increased, and the heat can be dissipated by both of the conduction and convection effects. Besides, the heat sink directly contacts the heat source, so that the heat conduction path can be reduced. Furthermore, the heat sink has a solid structure to contribute a more reliable strength and to be made by a simpler process.

### BRIEF DESCRIPTION OF THE DRAWINGS

The invention will become more fully understood from the detailed description and accompanying drawings, which are given for illustration only, and thus are not limitative of the present invention, and wherein:

FIGS. 1A and 1B are schematic diagrams of a heat sink according to a first embodiment of the invention;

FIGS. 2A and 2B are schematic diagrams of a heat sink according to a second embodiment of the invention;

FIG. 3 is a schematic diagram of a heat sink according to a third embodiment of the invention;

FIG. 4A is a schematic diagram of a heat sink according to a fourth embodiment of the invention;

FIG. 4B is a schematic side-view diagram of a heat sink according to an embodiment of the invention;

FIG. 5 is a schematic side-view diagram of a heat sink of the invention, showing the relative position of the heat sink and an electronic apparatus; and

FIGS. 6A to 6C are schematic side-view diagrams of the variations of a heat dissipation portion of a heat sink according to an embodiment of the invention.

### DETAILED DESCRIPTION OF THE INVENTION

The present invention will be apparent from the following detailed description, which proceeds with reference to the accompanying drawings, wherein the same references relate to the same elements.

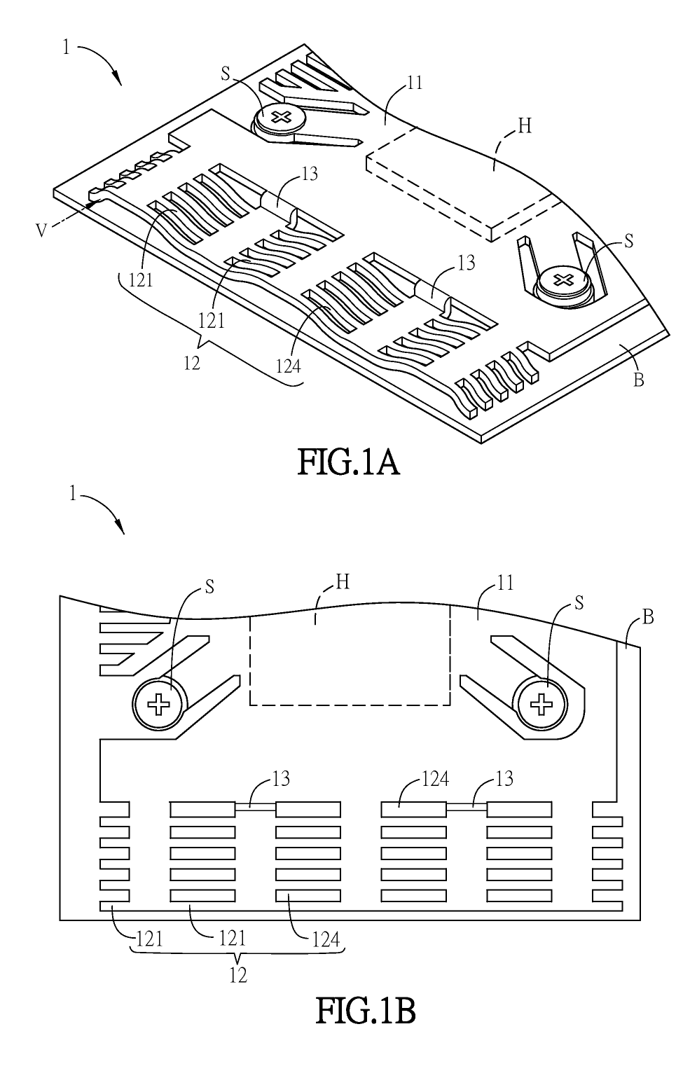

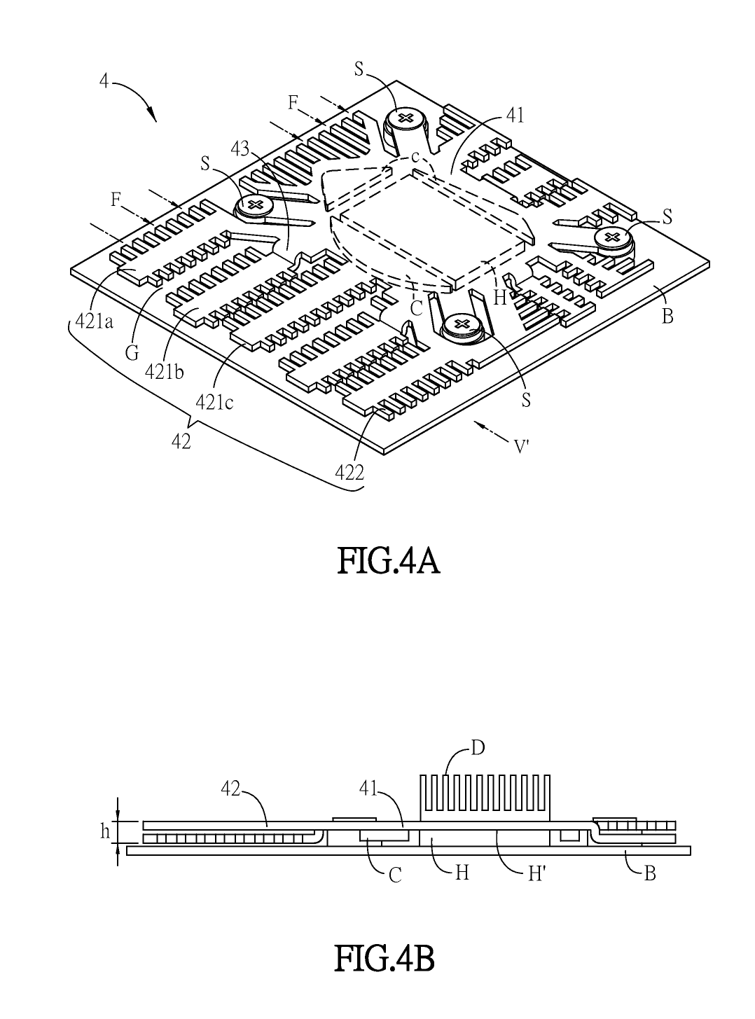

A heat dissipation apparatus, such as a heat sink, according to a preferred embodiment of the invention approximates to a rectangular form and provides the effect of heat conduction and dissipation. As shown in FIG. 4A, the heat conduction portion of the heat sink has at least four sides, and one of the sides is used as a main extending direction. Otherwise, the extending direction can be formed by the two adjacent sides extending outward, the two opposite sides extending outward, or the three or four sides extending outward. However, the invention is not limited thereto. In this embodiment, the main extending direction is formed by a single side extending outward and the other three sides are configured with simple heat dissipation structures, for example, as shown in FIGS. 1A˜3. Besides, the heat sink in this embodiment has a flat form.

FIG. 1A is a schematic diagram of a heat sink according to a first embodiment of the invention. As shown in FIG. 1A, the heat sink 1 includes a heat conduction portion 11 and a heat dissipation portion 12. The heat conduction portion 11 is made by at least one heat conduction material with a flat form and a thickness, and a flat portion thereof contacts a heat source H. In one embodiment, the heat source H can be a chip disposed on a circuit board, or a central processing unit (CPU), or other devices in need of heat dissipation. The heat dissipation portion 11 is extended outward from at least one side of the thickness of the heat conduction portion 11. Because the flat portion of the heat conduction portion 11 contacts the heat source H with a large area, the heat can be conducted to the heat dissipation portion 12 by the heat conduction portion 11.

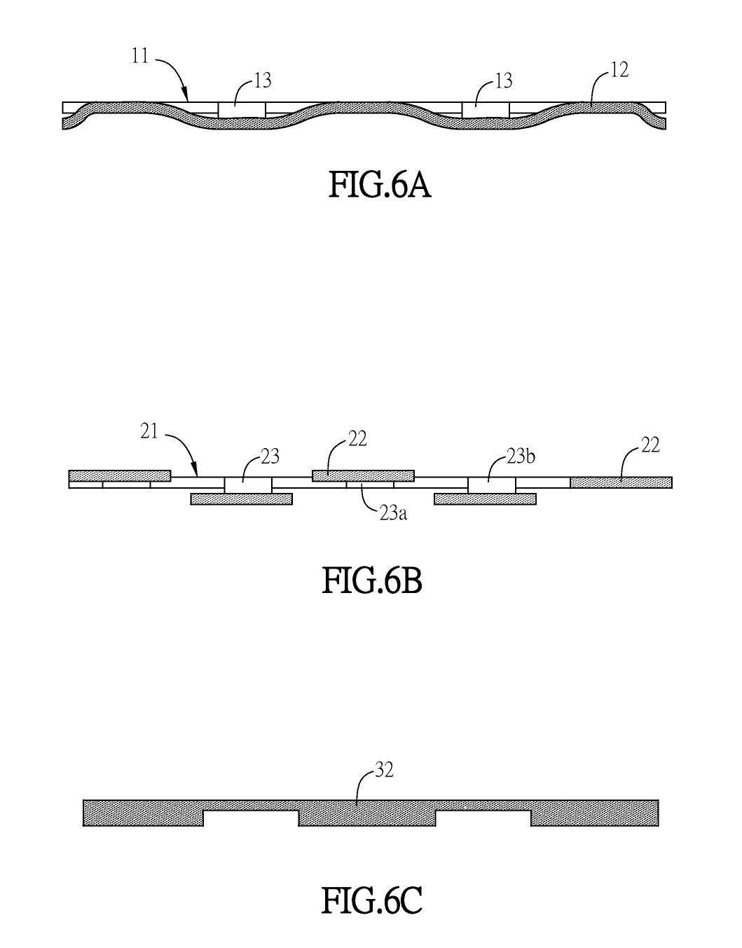

In this embodiment, the heat dissipation portion 12 includes a bending portion (including a curved portion in scope) 121. The bending portion 121 can have a wavy shape, a jagged shape, a ladder-like shape or an alternate arrangement (according to a view of the horizontal direction V denoted by the arrowhead). In FIGS. 1A and 6, the bending portion 121 is embodied in a wavy shape. Because the bending portion 121 has a bending structure, the heat dissipation area can be increased, and when a fan (not shown) is added to the heat sink, the windward area can be also increased so that a better heat dissipation effect can be provided. Besides, the bending structures, such as with a wavy shape, a jagged shape, a ladder-like shape or an alternate arrangement, can be disposed on the bending portion 121 periodically or non-periodically. Due to the bending portion 121, a difference in level 13 exists between the heat conduction portion 11 and the heat dissipation portion 12.

FIG. 1B is a top-view diagram of the heat sink in FIG. 1A. As shown in FIGS. 1A and 1B, the bending portion 121 of the heat dissipation portion 12 includes a plurality of holes 124. The holes 124 are through the bending portion 121 and become the channels which the air can flow through. The adjacent two holes 124 are disposed oppositely or adjacent to each other. When the heat sink is configured with an additional fan (not shown), the airflow generated by the fan can pass through the holes 124 to bring the heat out so that the heat dissipation effect can be improved.

In order to fix the heat sink 1 of the first embodiment to the top of the heat source H, the screws S are used to fix the flat heat sink 1 to a circuit board or another substrate B, as shown in FIGS. 1A and 1B, so that the heat sink 1 can be prevented from being loosed or moved. However, many other methods can be used to fix the heat sink, and the method of using screws in this embodiment is just for example but not for limiting the scope of the invention.

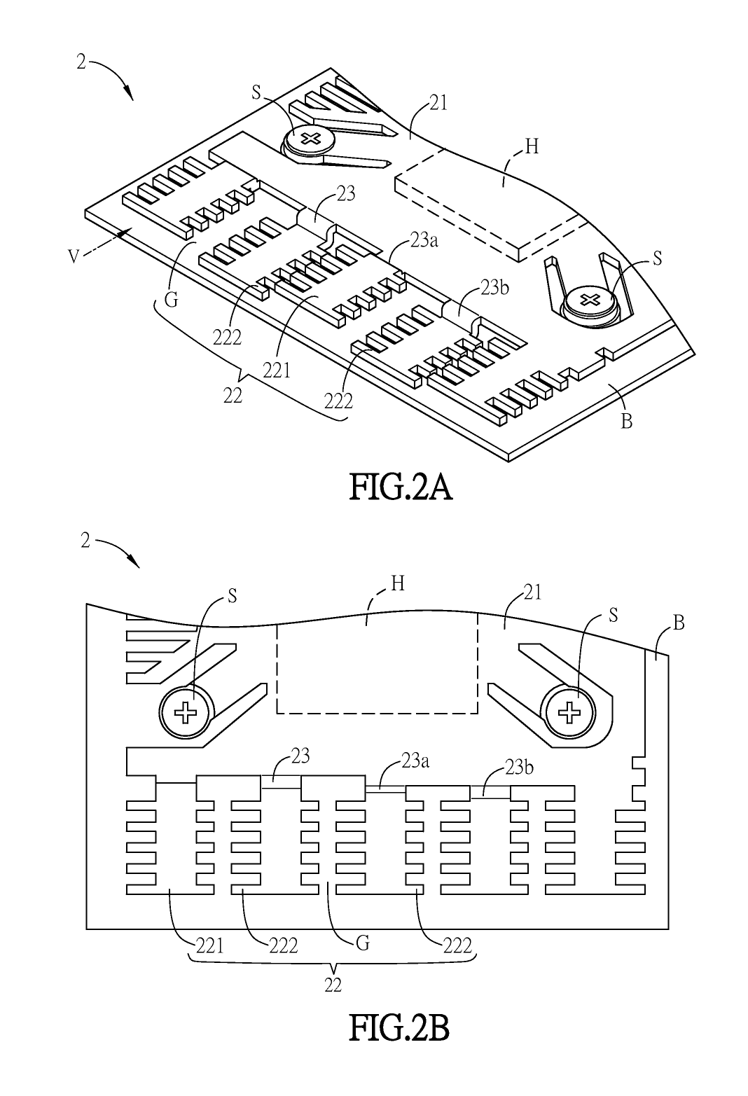

FIG. 2A is a schematic diagram of a heat sink of a second embodiment of the invention. As shown in FIG. 2A, the heat sink 2 includes a heat conduction portion 21 and a heat dissipation portion 22. A flat portion of the heat conduction portion 21 contacts a heat source H. The heat dissipation portion 22 is extended outward from at least one side of the thickness of the heat conduction portion 21. To be noted, the heat dissipation portion 22 includes at least a first branch 221 and a plurality of second branches 222. The second branch 222 is extended outward from one side of the thickness of the first branch 221 or from two sides of the thickness of the first branch 221, and FIG. 2A shows the latter case. The connection between the heat conduction portion 21 and the first branch 221 can have a height. In other words, the connection between the first branch 221 and the heat conduction portion 21 has a bending portion 23 along the horizontal direction. For example, the first branch 221 is higher than the heat conduction portion 21 by a height 23a and the first branch 221 is lower than the heat conduction portion 21 by a height 23b. Accordingly, the adjacent first branches 221 are disposed on the different levels, or the heat conduction portion 21 and the heat dissipation portion 22 are disposed on the different levels. As an embodiment, the connection between the first and second branches 221, 222 also can have a height (not shown) for increasing the heat dissipation area.

In other embodiments, the two second branches oppositely extended from the adjacent first branches can be connected to each other so that the heat can be conducted through the adjacent first branches and the heat conduction effect can be thus enhanced. From another viewpoint, in the heat sink 1 in FIG. 1A, the bending portion 121 of the heat dissipation portion 12 can be regarded as the above-mentioned case where the two second branches are connected to each other.

FIG. 2B is a top-view diagram of the heat sink in FIG. 2A. As shown in FIG. 2B, from a top view, an interval G exists between the adjacent first branches 221 and between the adjacent second branches 222. The interval G is not limited in size. When the heat sink 2 is configured with an additional fan (not shown), airflow passing through the interval G is to improve the heat dissipation effect.

According to the side view of the heat dissipation portion 22 as shown in FIG. 6B taken along the horizontal direction V denoted by the arrowhead, the first and second branch 221 and 222 can have a wavy shape, a jagged shape, a ladder-like shape or an alternate arrangement. In FIG. 2A, the ladder-like shape is taken as an example, and the adjacent first branches 221 are disposed on the different levels due to the heights 23a and 23b. Because the interval G exists between the adjacent first branches 221 and between the adjacent second branches 222, the heat dissipation portion 22 has some unconnected structures. The first branches 221 are parallel to each other approximately.

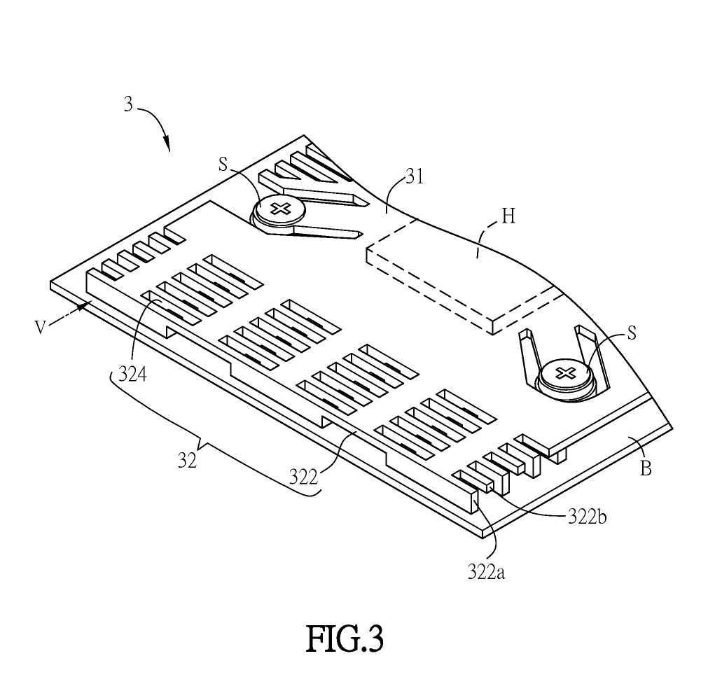

FIG. 3 is a schematic diagram of a heat sink according to a third embodiment of the invention. As shown in FIG. 3, the heat sink 3 includes a heat conduction portion 31 and a heat dissipation portion 32. The heat dissipation portion 32 includes a plurality of bending portions 322 and a plurality of holes 324. To be noted, at least one of the bending portion 322 can have different thicknesses. In FIG. 3, because the bending portion 322a is thicker than the bending portion 322b and the bending portions 322a and 322b are arranged alternately, the thinner bending portion 322b exists between the two adjacent thicker bending portions 322a so that the underside of the heat dissipation portion 32 can provide some channels for the airflow. When the heat sink 3 is configured with an additional fan (not shown), the airflow generated by the fan can pass through the holes and channels to bring the heat out so as to improve the heat dissipation effect. The side view according to the horizontal direction V denoted by the arrowhead in FIG. 3 is shown in FIG. 6C. Because the heat dissipation principle of the heat sink 3 in FIG. 3 is the same as the heat sinks of the above embodiments, it is not described here for the conciseness.

FIG. 4A is a schematic diagram of a heat sink according to a fourth embodiment of the invention, and the heat sink 4 is formed by the structure of the second embodiment. As shown in FIG. 4A, different from the second embodiment, the first branch 421c is substantially longer than that of the first branch 221 shown in FIG. 2A so that more numbers of the second branches 422 can be formed. Moreover, the connection between the first branch and the heat conduction portion 41 is varied. For example, the connection between the first branch 421b and the heat conduction portion 41 has a bending portion 43 along the horizontal direction. When a fan (not shown) is disposed near the heat sink 4 and the wind of the fan blows to the heat sink 4 along the wind direction F, the air will sequentially passes through the underside of the first branch 421a and the top side of the first branch 421b to become the main airflow, and the heat dissipation effect can be thus enhanced. Because the heat dissipation principle of the heat sink 4 in FIG. 4A is the same as the heat sinks of the above embodiments, it is not described here for the conciseness.

FIG. 4B is a side-view diagram of the heat sink 4 in FIG. 4A according to a view of the horizontal direction V′ denoted by the arrowhead in FIG. 4A. As shown in FIGS. 4A and 4B, a flow guiding structure C can be disposed in the space formed by a side of the heat source H and the level below the surface H′ of the heat source H contacting the heat conduction portion 41. When the heat sink 4 is configured with an additional fan (not shown), the fan can be disposed along the direction perpendicular to the normal vector of the flat portion of the heat conduction portion 41 and the wind of the fan blows towards the wind direction F (in FIG. 4A). Accordingly, when the air blows to the flow guiding structure C (also the heat source H), it will be guided to the heat dissipating portion 42 with a smooth air split so that the airflow can be distributed properly for more expanding the heat dissipation effect of the heat dissipation portion 42. To be noted, the heat sinks of the foregoing embodiments also can be varied like the heat sink 4.

Moreover, when the space of the heat sink is allowable, the conventional means for the heat dissipation, such as heat dissipation pillars, heat dissipation fins, heat pipe or their combinations, also can be used, in addition to the dissipation methods of the invention. As shown in FIG. 4B, the flat portion of the heat conduction portion 41 can be extended to provide another heat dissipation structure D opposite to the heat source H. The heat dissipation structure D can be a pillar, fin or their combination. The heat dissipation structure D is connected to the flat portion of the heat conduction portion 41 opposite to the heat source H for enhancing the heat dissipation. Likewise, the heat dissipation element (not shown), such as a heat pipe or a fin, also can be disposed on the side of the heat source H that is not connected to the heat conduction portion 41 for more enhancing the heat dissipation. To be noted, the heat sinks of the foregoing embodiments also can be varied likewise.

To be noted, the heat dissipation portion can include a branch structure. For example, the first branch branches as the second branch, and the cross-sectional area of the second branch is less than or equal to that of the first branch. The first branch can provide the major heat dissipation effect and the second branch can provide some heat dissipation area and channels for the airflow. Therefore, the width or thickness of the second branch is often less than that of the first branch. For the application, the second branch can further branch as a third branch, and the cross-sectional area of the third branch is less than or equal to that of the second branch. However, the invention is not limited thereto.

The heat dissipation portion can be regarded as the extension of the heat conduction portion, and includes a branch structure near the heat conduction portion for avoiding an overlong heat conduction path. The bending portion of the heat dissipation portion also can achieve the same effect. Besides, the holes of the heat dissipation portion can make the convection so as to provide the air cooling effect.

The heat conduction portion and the heat dissipation portion can be made by the same or different material. For example, the heat conduction portion and the heat dissipation portion are made by the same metal of high conductivity, such as copper or aluminum, or the heat conduction portion is made by copper while the heat dissipation portion is made by aluminum. To be noted, the heat conduction portion and the heat dissipation portion can be integrated into a single structure. When they are integrated into one piece, the structure will be simpler and doesn't need a process of connection. Besides, because the heat conduction portion and the heat dissipation portion are both solid structures, they have better structural strength, in comparison with the conventional thin-type heat pipe or vapor chamber, and the manufacturing process thereof is simpler with a higher yield and lower cost.

The heat conduction portion and the heat dissipation portion can have the same or different thickness and/or level along the direction perpendicular to the heat source H. As shown in FIG. 4B, a part of the heat dissipation portion 42 has a lower level. The thickness h of the heat dissipation portion 42 also can be varied, such as increased. By the variation of the thickness and/or level, the level below the surface H′ of the heat source H contacting the heat conduction portion 41 can be configured with a heat dissipation structure so that the narrow or flat space of the electronic apparatus can be utilized more effectively. To be noted, the heat sinks of the foregoing embodiments also can be varied likewise.

There are approximately four sides according to a view of the plane formed by the heat sink as shown in FIG. 4A. At least one of the sides can be configured with a blocking wall (not shown) that is about parallel to the air-outlet direction and disposed adjacent to the heat sink 4, so the airflow generated by the fan can pass through the whole channels to bring the heat out. Likewise, the top side of the surface of the heat conduction portion 41 opposite to the heat source H also can be configured with a blocking wall that is parallel to the plane of the heat sink 4 for achieving the same effect. To be noted, the heat sinks of the foregoing embodiments also can be varied likewise.

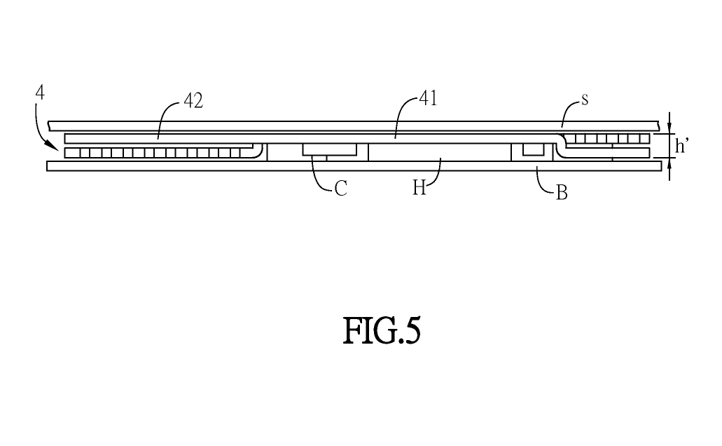

FIG. 5 is a schematic diagram of a heat sink (the fourth embodiment as an example) of the invention, showing the relative position of the heat sink and an electronic apparatus. As shown in FIG. 5, the heat source H (e.g. a chip) is disposed on the circuit board or another substrate B, such as a printed circuit board (PCB), and a component s (such as a keyboard or panel) disposed inside the housing of the electronic apparatus is over the heat source H. The heat sink 4 is just disposed within the space formed by top side of the substrate B with the heat source H and the underside of the component s, and the space is narrow or flat. To be noted, the height h′ of the heat sink is between 0.5 mm and 6.5 mm, so the heat sink is very suitable to this kind of narrow or flat space. The position of the heat sink relative to the electronic apparatus is not limited in the invention.

Moreover, because the heat source H can be a chip, CPU, or other devices in need of heat dissipation, it can be disposed on a circuit board or another substrate B. When the heat conduction portion and the heat dissipation portion of the heat sink is disposed over the heat source H, their thickness or level can be partially changed according to the components on the substrate B. For example, the heat dissipation portion can be reduced in thickness or raised in level so as to become an uneven structure for avoiding the interference with the components on the substrate B.

Besides, any surface of the heat conduction portion and heat dissipation portion can be configured with a plurality of holes, protrusions, grooves or their combinations for further increasing the heat dissipation area.

In summary, according to the heat sink of the invention applied to a narrow space, a heat conduction material of a certain thickness disposed on the top of the heat source is expanded horizontally to generate a branch structure and vertically changed in shape. Therefore, the heat sink is designed on the basis of the concept of horizontal and vertical structure so as to create three-dimensional airflow channels so that the windward area and the heat exchange area between the heat sink and the air can be both increased and the heat can be dissipated by both of the conduction and convection effects. Besides, the heat sink directly contacts the heat source, so the heat conduction path can be reduced. Furthermore, the heat sink has a solid structure so it can contribute a more reliable strength and can be made by a simpler process.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A heat sink, comprising:
a heat conduction portion having a thickness, a flat portion of which contacts a heat source; and
a heat dissipation portion extended from at least one side of the thickness of the heat conduction portion, and including at least a bending portion including a plurality of holes.

2. The heat sink as recited in claim 1, wherein the bending portion has a wavy shape, a jagged shape, a ladder-like shape or an alternate arrangement, or their combinations.

3. The heat sink as recited in claim 1, wherein the heat conduction portion and the heat dissipation portion are integrated into a single structure.

4. The heat sink as recited in claim 1, wherein a difference in level exists between the heat conduction portion and the heat dissipation portion.

5. The heat sink as recited in claim 1, wherein the heat conduction portion and the heat dissipation portion have the same or different thickness and/or level along the direction perpendicular to the heat source.

6. The heat sink as recited in claim 1, wherein the flat portion of the heat conduction portion is extended to provide a heat dissipation structure that is opposite to the heat source and has a pillar or fin or their combination.

7. The heat sink as recited in claim 1, wherein at least a flow guiding structure is disposed in the space formed by a side of the heat source and the flat portion of the heat conduction portion contacting the heat source.

8. The heat sink as recited in claim 1, wherein the height of the heat sink is between 0.5 mm and 6.5 mm.

9. A heat sink, comprising:
a heat conduction portion having a thickness, a flat portion of which contacts a heat source; and
a heat dissipation portion extended from at least one side of the thickness of the heat conduction portion, and including at least a first branch and a plurality of second branches which are extended outward from at least one side of the thickness of the first branch.

10. The heat sink as recited in claim 9, wherein when the heat dissipation portion includes a plurality of first branches, at least two of the first branches are disposed on different levels.

11. The heat sink as recited in claim 9, wherein the heat conduction portion and the heat dissipation portion are integrated into a single structure.

12. The heat sink as recited in claim 9, wherein a difference in level exists between the heat conduction portion and the heat dissipation portion.

13. The heat sink as recited in claim 9, wherein the heat conduction portion and the heat dissipation portion have the same or different thickness and/or level along the direction perpendicular to the heat source.

14. The heat sink as recited in claim 9, wherein the second branches have the same or different interval therebetween.

15. The heat sink as recited in claim 9, wherein the two second branches oppositely extended from the adjacent first branches are connected to each other.

16. The heat sink as recited in claim 9, wherein at least two of the second branches are disposed on different levels.

17. The heat sink as recited in claim 9, wherein the flat portion of the heat conduction portion is extended to provide a heat dissipation structure that is opposite to the heat source and has a pillar or fin or their combination.

18. The heat sink as recited in claim 9, wherein at least a flow guiding structure is disposed in the space formed by a side of the heat source and the flat portion of the heat conduction portion contacting the heat source.

19. The heat sink as recited in claim 9, wherein the height of the heat sink is between 0.5 mm and 6.5 mm.
